(19) United States
(12) Patent Application Publication
(10) Pub. No.: US 2016/0380326 A1
(43) Pub. Date: Dec. 29, 2016

(54) FLEXIBLE CIRCUIT STRUCTURES FOR HIGH-BANDWIDTH COMMUNICATION

(71) Applicants: Stephen H. Hall, Forest Grove, OR (US); Vijay Kasturi, Hillsboro, OR (US); Michael T. Hamann, Portland, OR (US)

(72) Inventors: Stephen H. Hall, Forest Grove, OR (US); Vijay Kasturi, Hillsboro, OR (US); Michael T. Hamann, Portland, OR (US)

(21) Appl. No.: 14/752,639

(22) Filed: Jun. 26, 2015

(51) Int. Cl. H01P 3/08; H05K 1/02

(52) U.S. Cl. CPC H01P 3/081; H05K 1/0237; H05K 1/028

(57) ABSTRACT

Techniques and mechanisms for enabling small radius bending of a flexible circuit. In an embodiment, the flexible circuit includes a first section, a second section and a third section between the first section and second section. Stacked structures of the first section include a first trace portion and a first conductor, and stacked structures of the second section include a second trace portion and a second conductor. In another embodiment, a first span structure of the third section exchanges a first signal between the first trace portion and the second trace portion while the first conductor and the second conductor are maintained at a reference potential. While the first signal is exchanged, a second span structure of the third section—coplanar with the first span structure—is maintained at the reference potential or propagates a second signal complementary to the first signal.

### BACKGROUND

1. Technical Field

Embodiments of the invention relate generally to flexible circuit structures and more particularly, but not exclusively, to exchanging signals across a bend of a flexible printed circuit.

2. Background Art

In various laptop, ultrabook, tablet, smartphone and other designs, it is desirable to support electrical signaling across a hinge. Implementing such signal exchanges with flexible printed circuit (FPC) technology has traditionally been constrained by a trade-off between a maximum allowable signal bandwidth and a minimum FPC dynamic bend radius.

Various conventional circuit design techniques to protect signal integrity include routing a signal line along, and proximate to, the surface of a conductive layer that is to be maintained at some constant voltage such as a reference (e.g., ground) potential. Such a signal line is typically disposed between two reference planes in a conventional three-layer arrangement, known as a stripline, to mitigate loss of signal integrity due to radio-frequency interference (RFI) or other electromagnetic interference (EMI) problems. However, these conventional arrangements tend to limit their implementation in flexible circuit applications. For example, where a FPC includes a stripline or other conventional arrangement of multiple stacked metal layers, bending of such a FPC would result in the metal layers each being subjected to a different respective one of various compression forces and stretching forces (e.g., depending on the bending of a midline plane of the FPC and depending on the respective locations of such metal layers relative to the midline plane). Consequently, such FCPs typically have a minimum dynamic bend radius (a radius of bending that occurs repeatedly) of more than 7.5 mm.

Modern form factors for various types of electronic devices are trending toward very thin (low z-height) industrial designs. This severely limits the ability to incorporate existing FCPs into the design of very thin, hinged systems. As the functionality of successive generations of electronic devices continues to grow and as such generations continue to trend toward thinner form factors, there is expected to be an increasing demand for high-bandwidth signaling across tightly curved flexible circuit structures.

### BRIEF DESCRIPTION OF THE DRAWINGS

The various embodiments of the present invention are illustrated by way of example, and not by way of limitation, in the figures of the accompanying drawings and in which:

FIG. 1 is a perspective view illustrating elements of a flexible circuit device according to an embodiment.

FIG. 2A is a layout diagram illustrating elements of a flexible circuit device according to an embodiment.

FIGS. 2B-2F are cross-sectional views each illustrating elements of the flexible circuit device of FIG. 2A.

FIG. 3 is a flow diagram illustrating elements of a method for operating a flexible circuit according to an embodiment.

FIG. 4A is a layout diagram illustrating elements of a flexible circuit device according to an embodiment.

FIGS. 4B-4F are cross-sectional views each illustrating elements of the flexible circuit device of FIG. 4A.

FIG. 5A is a layout diagram illustrating elements of a flexible circuit device according to an embodiment.

FIGS. 5B-5D are cross-sectional views each illustrating elements of the flexible circuit device of FIG. 5A.

FIG. 6 is a layout diagram illustrating elements of a flexible circuit device according to an embodiment.

FIG. 7 is an exploded view of a system including flexible circuit structures according to an embodiment.

FIG. 8 is a functional block diagram illustrating elements of a computing system including flexible circuit structures according to an embodiment.

FIG. 9 is a functional block diagram illustrating elements of a mobile device including flexible circuit structures according to an embodiment.

### DETAILED DESCRIPTION

Embodiments discussed herein variously relate to flexible circuit structures that allow for small radius bending and that support high-bandwidth signal exchanges. For existing FPCs comprising a stripline or other conventional arrangement of stacked metal layers, bending of such a FPC typically results in the metal layers being variously subjected to different compression forces and/or stretching forces. Certain embodiments are a result of a realization that flexibility of a circuit to provide high-bandwidth signaling may be significantly improved by including in a section of the circuit a coplanar arrangement of conductive components to protect signal integrity, where the coplanar arrangement is different than a multi-layer arrangement of other corresponding components in an adjoining section (or sections) of the circuit. Although not limiting on certain embodiments, high-bandwidth (e.g., high frequency) signaling may support up to at least 1 Gigabit per second (Gb/s) data exchanges and, in some embodiments, data exchanges of up to at least 5 Gb/s—e.g., up to 10 Gb/s or 20 Gb/s.

While the present disclosure is described herein with reference to illustrative embodiments for particular applications, it should be understood that such embodiments are exemplary only and that the invention as defined by the appended claims is not limited thereto. Those skilled in the relevant art(s) with access to the teachings provided herein will recognize additional modifications, applications, and embodiments within the scope of this disclosure, and additional fields in which embodiments of the present disclosure would be of utility.

The technologies described herein may be implemented in one or more electronic devices. Non-limiting examples of electronic devices that may utilize the technologies described herein include any of various types of mobile devices and/or stationary devices, such as cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, wearable electronics, combinations thereof, and the like. Such devices may be portable or stationary. In some embodiments the technologies described herein may be employed in a desktop computer, laptop computer, smart phone, tablet computer, netbook computer, notebook computer, personal digital assistant, server, combinations thereof, and the like. More generally, the technologies described herein may be employed in any of various electronic devices configured to exchange signals across a hinge or capable of coupling to exchange signals across a hinge.

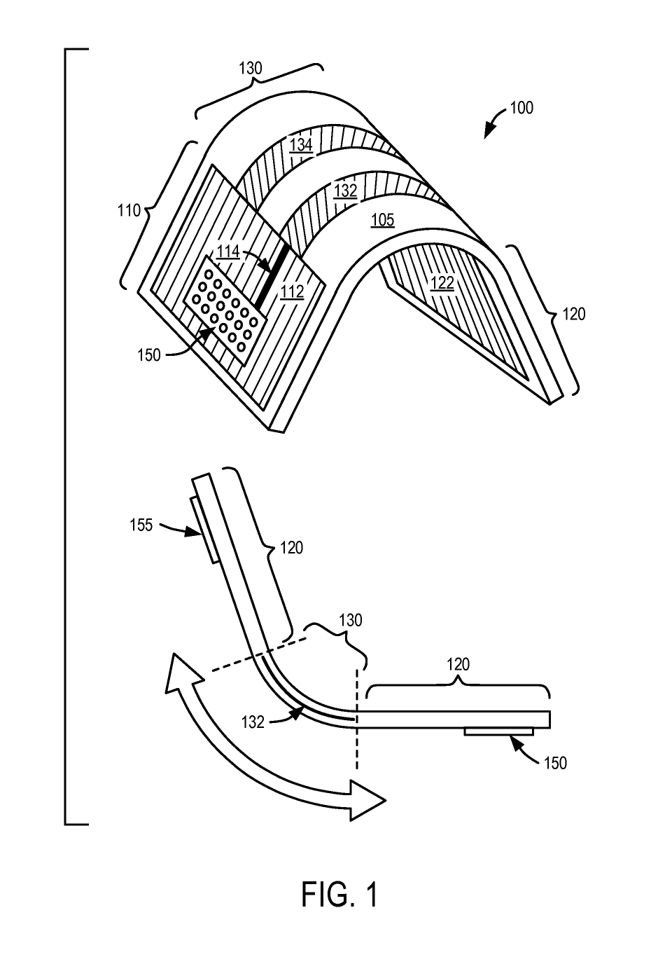

FIG. 1 illustrates elements of a device 100 including flexible circuit structures according to an embodiment. Device 100 may comprise, or operate as a component of, any of a variety of electronic devices including, but not limited to, a smartphone, laptop, palmtop, tablet, wearable device, etc. Although shown in FIG. 1 as being bent, device 100 may alternatively be flat or variously articulated at different times.

Device 100 is just one example of a device, such as a FPC, that includes a flexible section disposed between two adjoining sections, the flexible section to aid in signal communication between the adjoining sections. Flexible structures (referred to herein as “span structures”) of such a flexible section may be coplanar with one another and extend across, or span, the flexible section to variously couple to respective structures of the adjoining sections. The corresponding structures of the adjoining sections may form or otherwise be part of respective stacked metal layers of the adjoining sections. Span structures of the flexible section may be conductive—e.g., where one span structure is coupled to exchange an electrical signal and another span structure is to exchange another electrical signal or is to be maintained at a ground voltage or other reference potential.

In the illustrative embodiment of FIG. 1, device 100 includes a dielectric material 105 and conductive structures variously disposed therein and/or thereon. Dielectric material 105 may include, for example, polyimide or any of a variety of other dielectrics used in conventional FPCs. Sections 110, 120 of device 100 may be configured to exchange signals with each other across a flexible section 130 of device 100. For example, section 110 may include at least one signal line—e.g., represented by the illustrative signal line 114—that is to exchange a signal with another signal line (not shown) of section 120. Each of sections 110, 120 may further include at least one layer of conductive material (referred to herein as a “reference plane”) that, during operation of device 100, is to be maintained at some constant reference potential such as a ground voltage. Such reference planes—e.g., as illustrated by the respective planes 112, 122 of sections 110, 120—may variously aid in protecting the integrity of the signal exchanged with signal line 114.

In the illustrative embodiment shown, device 100 further includes hardware interfaces 150, 155 each including one or more respective pads, pins, balls and/or other conductive contacts coupled to further exchange the signal to device 100 and from device 100. One or both of hardware interfaces 150, 155 may conform to any of a variety of connector standards such as that of a Peripheral Component Interconnect (PCI) specification, a PCI Express (PCIe) specification or the like. In other embodiments, one or both of hardware interfaces 150, 155 may be omitted from device 100—e.g., where source circuitry to generate the signal and/or sink circuitry to receive the signal is integrated in or on dielectric material 105.

Section 130 may include flexible span structures 132, 134 that are coplanar with one another—e.g., where a midline (or other) plane between opposite sides of dielectric material 105 extends through, and in parallel with, each of span structures 132, 134. A side-view of device 100 in FIG. 1 illustrates a location of span structure 132 within dielectric material 105 according to an embodiment. Span structure 132 (or alternatively, span structure 134) may be coupled to exchange across section 130 a signal that has been, or is to be, communicated with signal line 114. Span structure 134 may be coupled to aid in protecting the integrity of such a signal. For example, span structure 134 may be coupled to each of reference planes 112, 122. In such an embodiment, span structure 134 may be maintained at a reference potential during operation of device 100 to aid in protection of the signal from EMI during its exchange via span structure 132. Alternatively, the signal exchanged by span structure 132 may be one signal of a differential signal pair, where span structure 134 is instead coupled to exchange between other signal lines (not shown) of sections 110, 120 the other signal of that same differential signal pair. Proximity of span structures 132, 134 to one another may aid in such a differential signal pair being self-referenced with one another, and thus less susceptible to EMI.

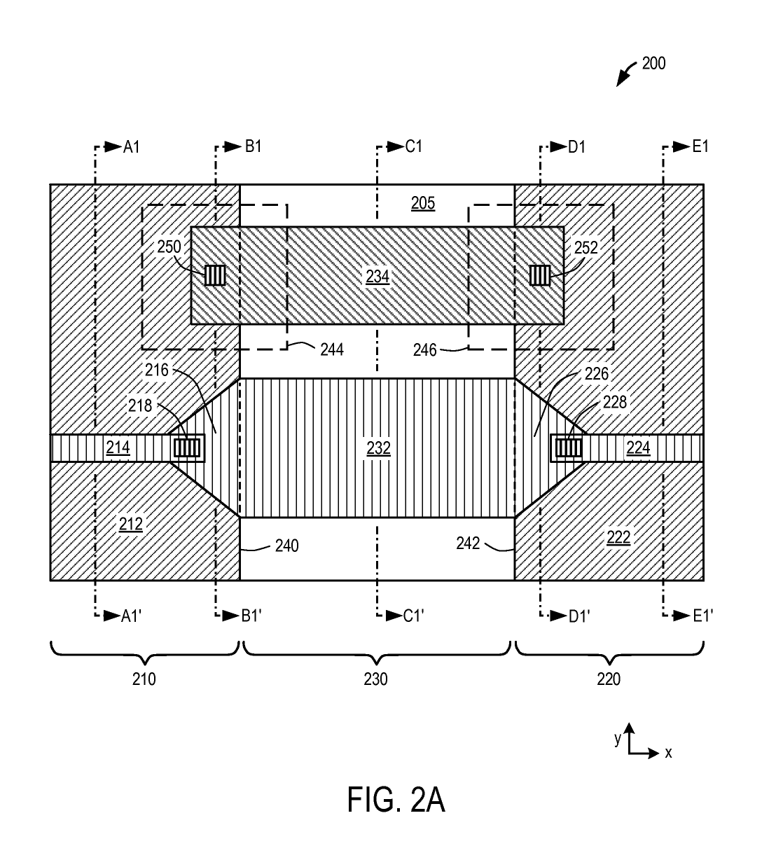

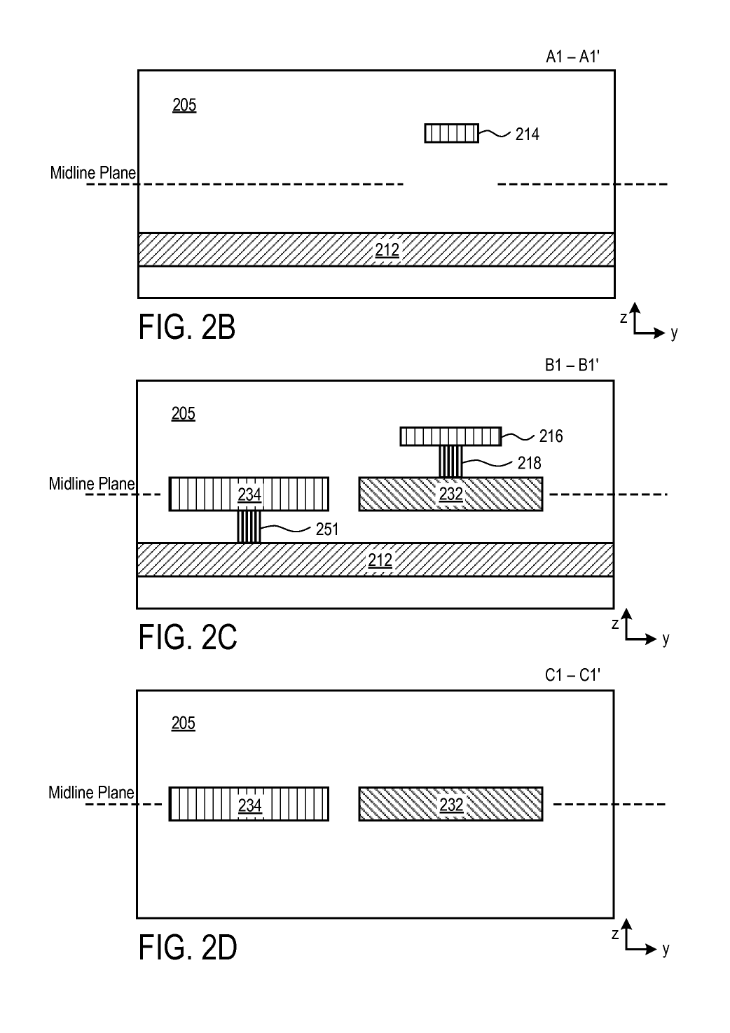

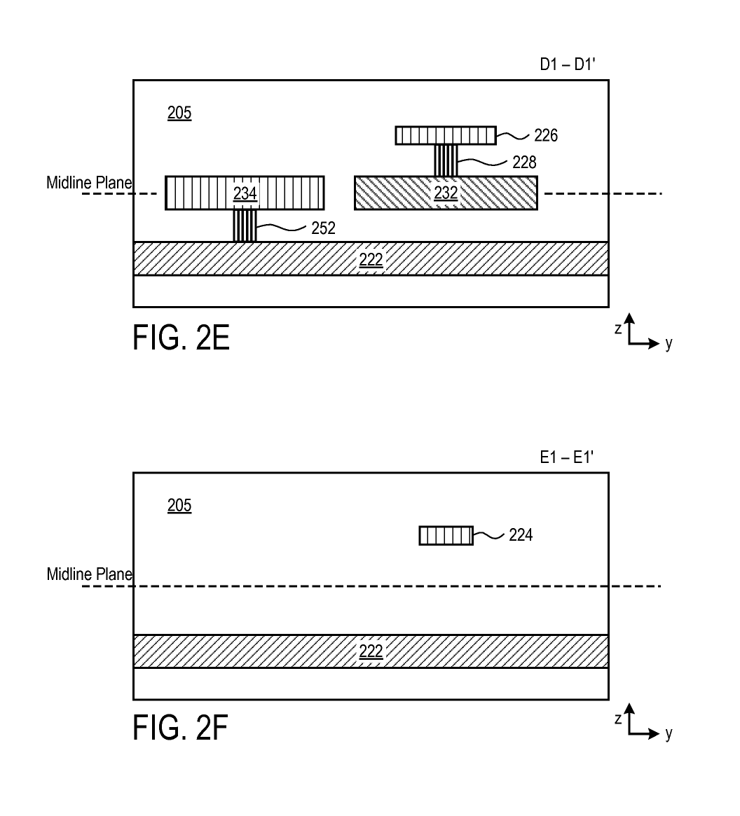

FIGS. 2A-2F variously illustrate elements of a device 200 including flexible circuit structures according to an embodiment. Device 200 may include some or all of the features of device 100, for example. As illustrated by the top view shown in FIG. 2A, device 200 may include sections 210, 220, 230 that, for example, correspond functionally to sections 110, 120, 130 of device 100. Device 200 includes a dielectric material 205 such as polyimide, Teflon, liquid crystal polymer and/or any of various other dielectrics that may be formed to allow for flexibility of at least section 230. Conductive structures variously formed in and/or on dielectric material 205 may enable an exchange of a signal between sections 210, 220 via section 230, where section 230 includes coplanar structures to protect an integrity of such a signal while providing improved flexibility of section 230. In an embodiment, other structures of sections 210, 220 to also protect the integrity of the signal may include structures arranged in a stacked configuration and/or one or more structures that are not coplanar with the structures of section 230. Such conductive structures may comprise copper, gold, tin and/or other metals used, for example, in conventional FCPs. Processing to fabricate such structures may include selective masking, deposition (e.g., sputtering, plating, etc.), etching and/or other operations adapted from conventional circuit manufacturing techniques. The details of such conventional techniques are not described herein to avoid obscuring certain features of various embodiments.

Sections 210, 220 may include respective conductive trace portions 214, 224 (e.g., including some or all of signal line 114) to exchange a signal with each other via a span structure 232 of section 230. Although certain embodiments are not limited in this regard, a conductive tapered portion 216 may be disposed between trace portion 214 and span structure 232 to mitigate impedance mismatch and/or to otherwise provide for a smooth transition of an electrical field for a signal exchange between trace portion 214 and span structure 232. Alternatively or in addition, a similar conductive tapered portion 226 may be disposed between trace portion 224 and span structure 232. Span structure 232 may be at a different level in dielectric material 205—e.g., at a different height along a z-dimension—than a corresponding level of trace portion 214 and/or of trace portion 224. For example, vias 218, 228 may extend vertically (along the z-dimension) to couple trace portions 214, 224 both to taper portions 216, 226, respectively, and to span structure 232.

Section 230 may further comprise a span structure 234 that is coupled—e.g., via structures 244, 246—to aid in protecting the integrity of the signal exchanged using span structure 232. Span structure 232 may be wider (e.g., in a y-dimension) than trace portion 214. Alternatively or in addition, span structure 232 may be narrower (e.g., in the y-dimension) than one or both of reference planes 212, 222. Alternatively or in addition, span structure 234 may be narrower than one or both of reference planes 212, 222. In the illustrative embodiment of device 200, structures 244, 246 include vias 250, 252 to couple span structure 234 to respective reference planes 212, 222 of sections 210, 220. During operation of device 200, reference planes 212, 222 may provide at least partial EMI protection of the signal as it variously propagates in trace portions 214, 224. Span structure 234 may provide at least partial EMI protection of the signal as it propagates in span structure 232. Reference planes 212, 222 may extend only outside of section 230—e.g., where one or both of span structures 232, 234 extend past respective sides 240, 242 of planes 212, 222.

In an embodiment, span structures 232, 234 are coplanar with one another in at least part of section 230. As used herein with respect to the location of span structures in a flexible circuit, “coplanar” refers to the characteristic of two span structures extending to (e.g., through) a same plane in the flexible circuit. For example, respective surfaces of such span structures may extend in parallel with one another and also in parallel with a same plane at a particular height (z-dimension) between opposite sides of the flexible circuit. The plane may be a midline plane that is halfway between opposite exterior surfaces of a dielectric material. In some embodiments including a microstrip configuration (i.e., comprising a 2 layer design with a single reference plane), the plane may not be a midline plane where the microstrip configuration is not symmetric in a z-direction stackup. Those skilled in the relevant art(s) with access to the teachings provided herein will recognize that such a plane may be either flat or curved, depending on whether the flexible circuit itself is currently flat or bent.

The coplanar configuration of span structures 232, 234—e.g., in lieu of a stacked arrangement—may allow for section 230 to have improved flexibility while also supporting high-bandwidth signal exchanges. For example, this configuration may allow for 1 Gb/s or more signaling while section 230 is flexed to a dynamic bending radius within, or even below, a range between 0.5 mm and 2.0 mm (as compared to minimum dynamic bending radii of 7 mm to 9 mm for conventional flexible circuits). By contrast, structures of section 210 (and/or structures of section 220) to also support the same high-bandwidth signal exchanges may form or otherwise be part of a stacked configuration. The respective cross-sectional views A1-A1′, B1-B1′, C1-C1′, D1-D1′ and E1-E1′ of FIGS. 2B through 2F variously illustrate one example of an arrangement of structures comprising device 200. However, other arrangements may be possible. For example, device 200 may omit vias 218, 228 in another embodiment wherein trace portions, 214, 224, tapered portions 216, 226 and span structure 232 are all coplanar with span structure 234. In some embodiments, sections 210, 220 each further include another trace portion to exchange an additional signal, where section 230 further comprises another span structure to propagate the additional signal. Alternatively or in addition, sections 210, 220 may each include another reference plane stacked with a respective one of reference planes 212, 222.

Although dimensions of device 200 may vary considerable in different embodiments, according to implementation-specific details, one or each of trace portions 214, 224 may have a respective (y-dimension) width in a range between 30 μm and 100 μm, for example. Alternatively or in addition, one or each of span portions 232, 234 may have a respective width in a range between 250 μm and 500 μm, for example. A width of separation between span portions 232, 234 may be in a range between 60 μm and 150 μm. In an embodiment, a width of section 230 between sides 240, 242 may be in a range between between 0.2 inches and 1.5 inches, for example. However, sections 210, 220 may not be limited to particular lengths, in some embodiments. These dimensions are merely illustrative of one example implementation of device 200, and are not limiting on other embodiments.

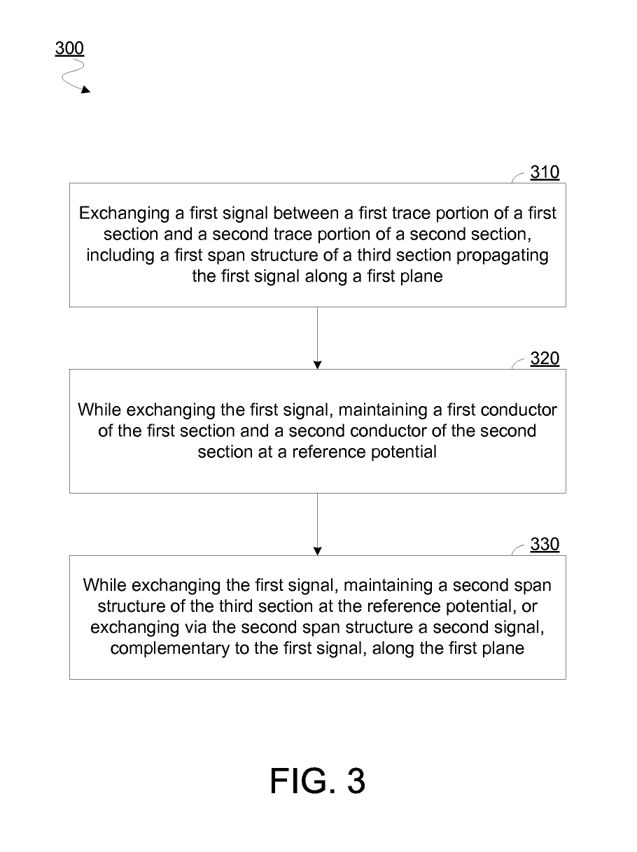

FIG. 3 illustrates elements of a method 300 according to an embodiment for operating a device including flexible circuit structures. Method 300 may operate a flexible circuit including some or all of the features of device 100 or device 200, for example.

In an embodiment, method 300 includes, at 310, exchanging a first signal between a first trace portion (e.g., trace portion 214) of the flexible circuit and a second trace portion (e.g., trace portion 224) of the flexible circuit. For example, a first section of the flexible circuit may include the first trace portion and a first conductor (e.g., reference plane 212) arranged in a first stacked—e.g., along a z-dimension—configuration between sides of the flexible circuit, wherein a second section of the flexible circuit includes the second trace portion and a second conductor (e.g., reference plane 222) arranged in a second stacked configuration between the sides of the flexible circuit. The exchanging at 310 may include a first span structure (e.g., span structure 232) propagating the first signal along a first plane—such as the midline plane of device 200—between the sides of the flexible circuit. A third section of the flexible circuit, such as section 230, may include the first span structure and a second span structure (e.g., span structure 234) that is coplanar with the first plane and the first span structure.

Method 300 may further comprise, at 320, maintaining the first conductor and the second conductor at a reference potential during the exchanging of the first signal at 310. The reference potential maintained at 320 may mitigate effects of EMI on propagation of the signal in the first trace portion and/or in the second trace portion. During the exchanging at 310, method 300 may further perform, at 330, a maintaining of the second span structure at the reference potential, or an exchanging via the second span structure of a second signal, complementary to the first signal, along the first plane. Use of the second span structure to maintain the reference potential or to exchange a second signal, complementary to the first signal (e.g., as in a differential signal pair), may aid in protecting integrity of the first signal.

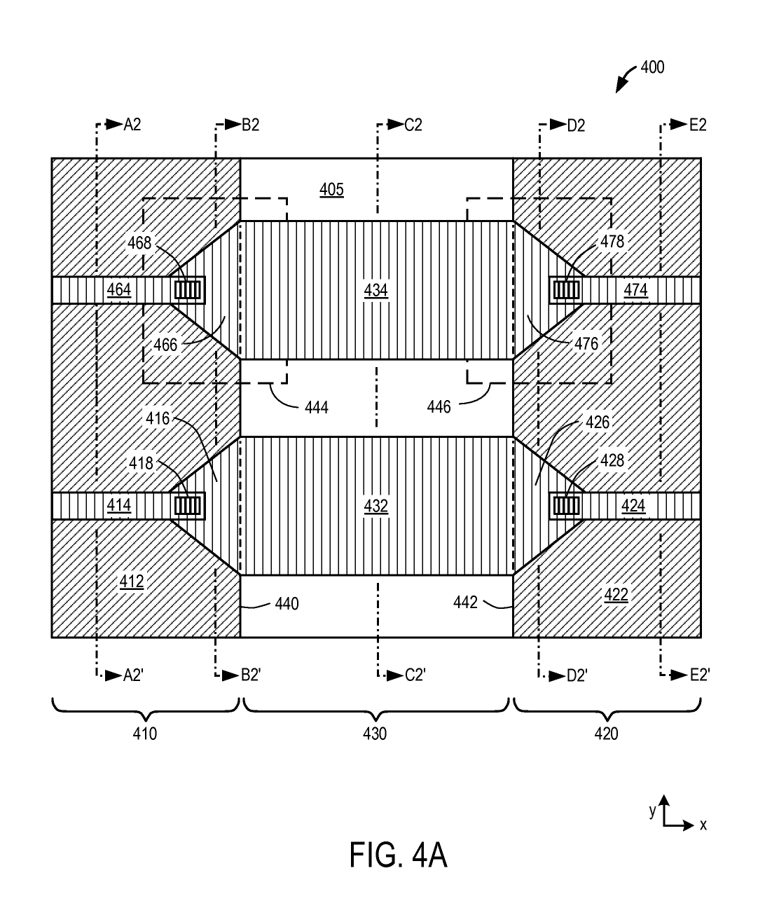

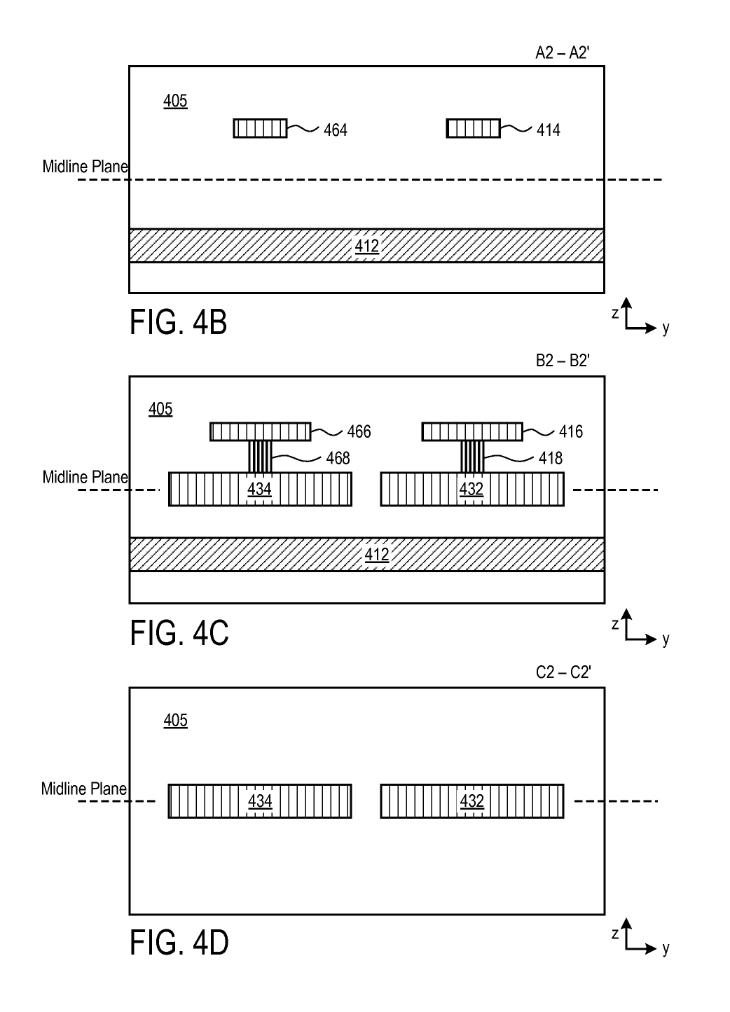

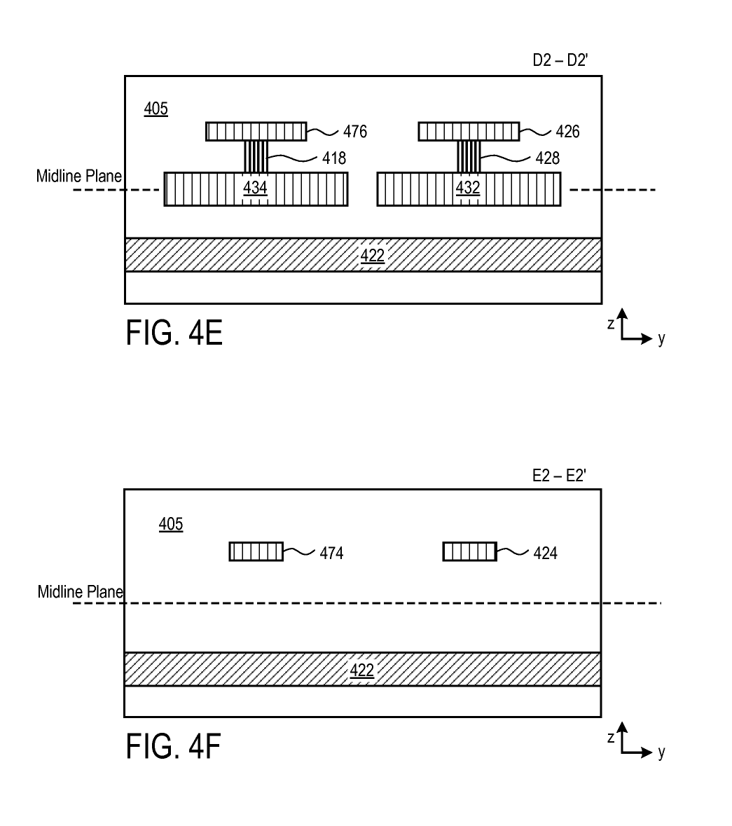

FIGS. 4A-4F variously illustrate elements of a device 400 including flexible circuit structures according to another embodiment. Device 400 may include some or all of the features of one of devices 100, 200. Operation of device 400 may include some or all of method 300, for example. As illustrated by the top view shown in FIG. 4A, device 400 may include sections 410, 420, 430 that, for example, correspond functionally to sections 110, 120, 130. Device 400 includes a dielectric material 405 and conductive structures, variously formed therein and/or thereon, to exchange multiple signals between sections 410, 420 via section 430.

For example, sections 410, 420 may include respective conductive trace portions 414, 424 to exchange a first signal with each other via a span structure 432 of section 430 that extends between respective sides 440, 442 of reference planes 412, 422. Sections 410, 420 may further include respective conductive trace portions 464, 474 to exchange a second signal with each other via another span structure 434—e.g., wherein the first signal and the second signal are complementary signals of a differential signal pair. Sections 410, 420 may each further comprise at least one reference plane—e.g., as illustrated by the respective reference planes 412, 422—to aid in mitigating the effect of EMI on the first signal and/or the second signal. In some embodiments, tapered portions 416, 426 mitigate signal reflection at opposing ends of span structure 432, and/or other tapered portions 466, 476 mitigate signal reflection at opposing ends of span structure 434.

Span structures 432, 434 are coplanar with one another in at least part of section 430. The respective cross-sectional views A2-A2′, B2-B2′, C2-C2′, D2-D2′ and E2-E2′ of FIGS. 4B through 4F variously illustrate one example of an arrangement of span structures 432, 434 relative to one other and to other structures comprising device 400. As shown in views B2-B2′ and D2-D2′, vias 418, 428 may couple span structure 432 to tapered portions 416, 426, respectively. Alternatively or in addition, vias 468, 478 may couple span structure 434 to tapered portions 466, 476, respectively. However, other arrangements may be possible. For example, device 400 may alternatively omit some or all of vias 418, 428, 468, 478 in another embodiment where trace portions 414, 424 are coplanar with span structure 432 and tapered portions 416, 426 and/or where trace portions 464, 474 are coplanar with span structure 434 and tapered portions 466, 476. Structures 444, 446 of device 400—e.g., including vias 468, 478 and tapered portions 466, 476—may be an alternative embodiment of structures 244, 246, for example.

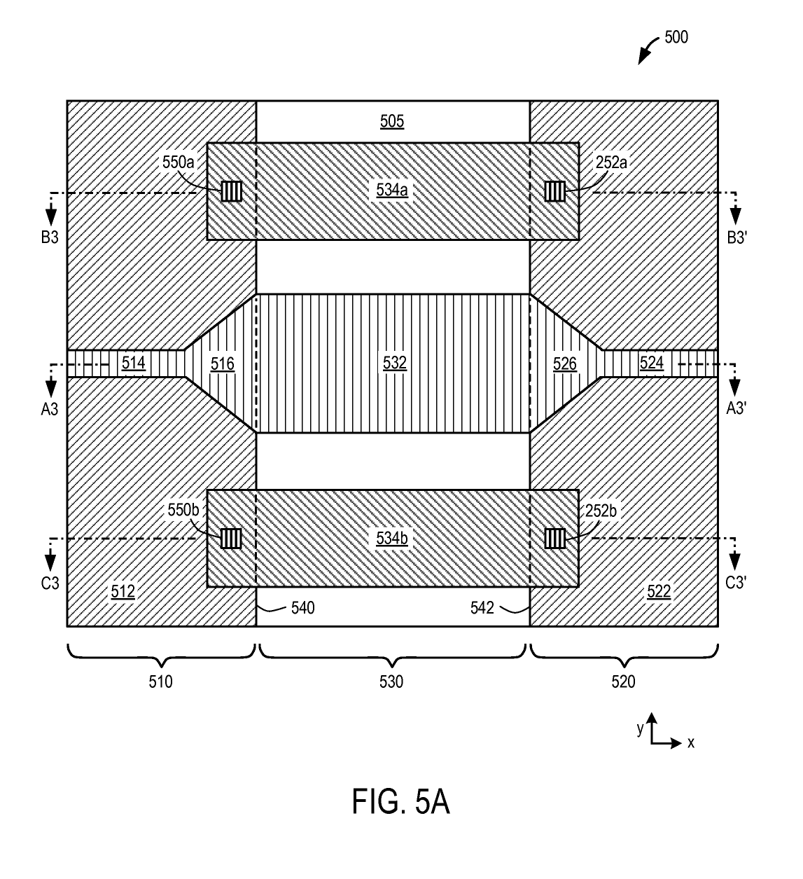

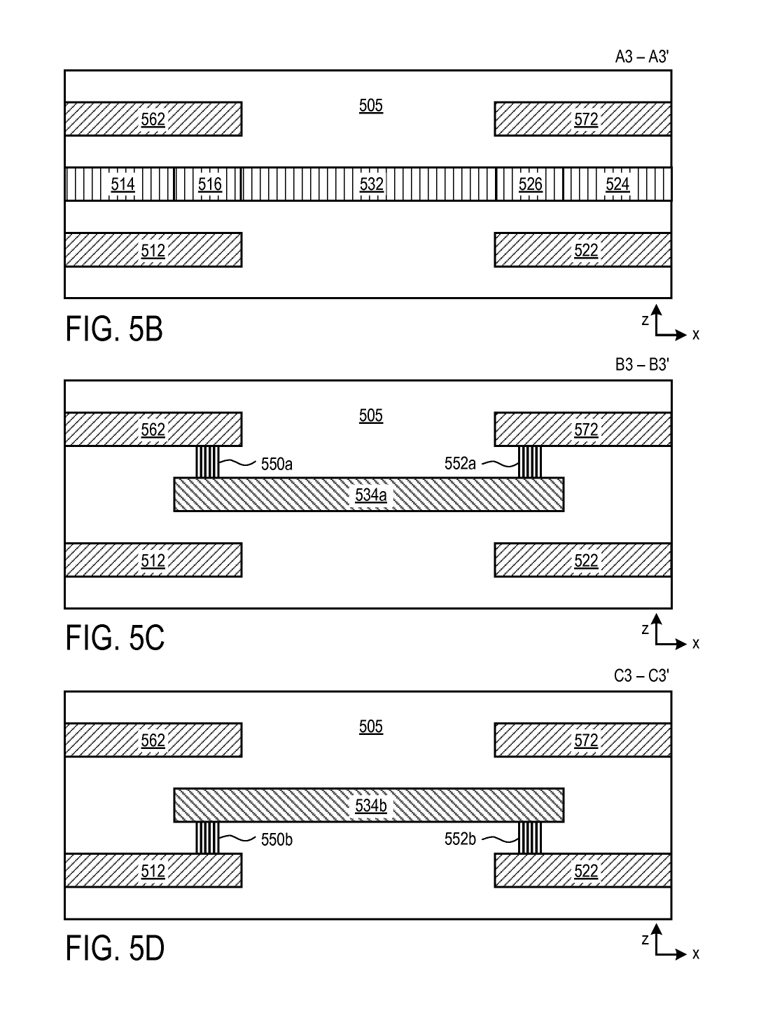

FIGS. 5A-5D variously illustrate elements of a flexible circuit device 500 according to another embodiment. Device 500 may include some or all of the features of device 100, for example. As illustrated by the top view shown in FIG. 5A, device 500 may include sections 510, 520, 530 that, for example, correspond functionally to sections 110, 120, 130. Device 500 includes a dielectric material 505 and conductive structures, variously formed therein and/or thereon, to exchange multiple signals between sections 510, 520 via section 530.

For example, as variously shown in respective cross-sectional views A3-A3′, B3-B3′ and C3-C3′ of FIGS. 5B through 5D, section 510 may include a stripline arrangement comprising stacked reference planes 512, 562 and a trace portion 514 disposed between reference planes 512, 562. Section 520 may include another stripline arrangement comprising stacked reference planes 562, 572 and a trace portion 524 disposed between reference planes 562, 572. Trace portions 514, 524 may be coupled to exchange a signal via a span portion 532 of section 530 that extends between respective sides 540, 542 of reference planes 512, 522—e.g., where tapered portions 516, 526 mitigate signal reflection at opposite ends of span structure 532.

To further protect signal integrity, section 530 may comprise span structures 534a, 534b on opposite sides of span structure 532. In an embodiment, vias 550a, 552a couple span structure 534a to reference planes 562, 572, respectively, and vias 550b, 552b couple span structure 534b to reference planes 512, 522, respectively. Accordingly, span structures 532, 534a, 534b may function as a coplanar stripline that is highly flexible—e.g., as compared to flexibility of sections 510, 520.

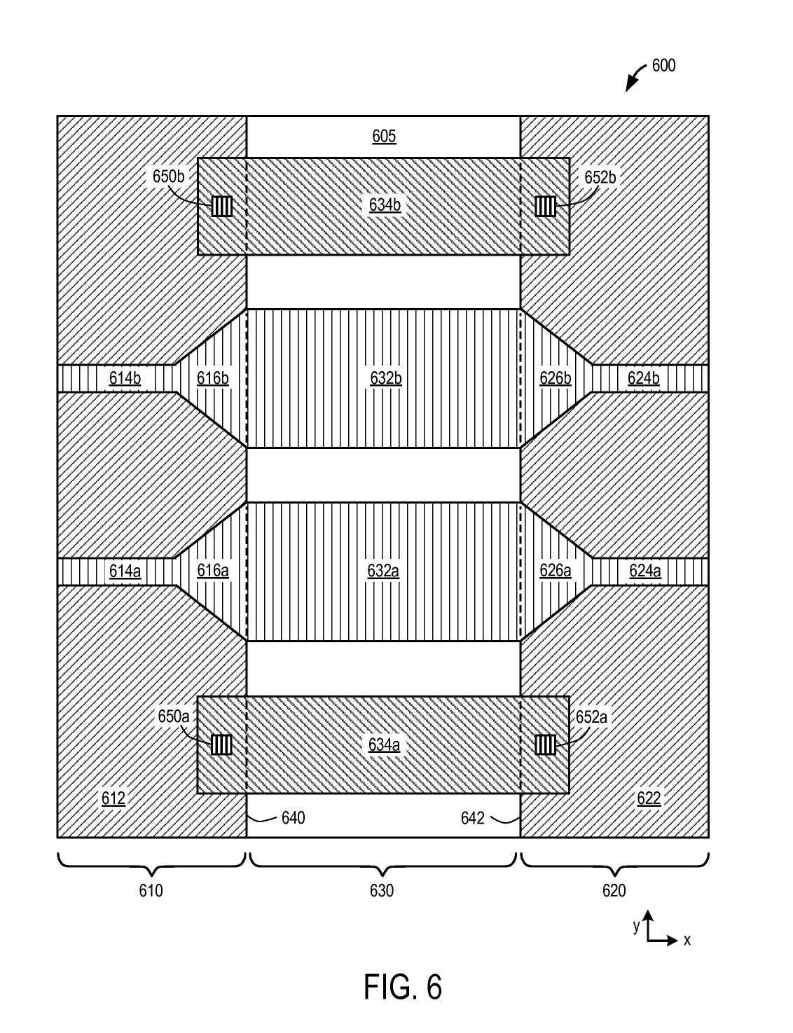

FIG. 6 illustrates elements of a flexible circuit device 600 according to an embodiment. Device 600 may include some or all of the features of device 500—e.g., where structures variously disposed in and/or on a dielectric material 605 of device 600 are configured to exchange signals between sections 610, 620 via section 630.

In an embodiment, section 610 includes a stripline arrangement comprising reference plane 612, another reference plane (not shown) stacked with reference plane 612 and trace portions 614a, 614b disposed between said reference planes. Section 620 includes another stripline arrangement comprising reference plane 622, another reference plane (not shown) stacked with reference plane 622 and trace portions 624a, 624b disposed between said reference planes. Span structures 632a, 632b and tapered structures 616a, 626a, 616b, 626b—e.g., corresponding functionally to span structures 432, 434 and tapered structures 416, 426, 466, 476, respectively—may variously aid in an exchange of a first signal between trace portions 614a, 624a and in an exchange of a second signal between trace portions 614b, 624b. The first signal and second signal may belong to the same differential signal pair, for example.

Span structures 632a, 632b may be coplanar with each other and with span structures 634a, 634b of section 630 that are each to be maintained at a reference potential during the signal exchanges via span structures 632a, 632b. In the illustrative embodiment shown, vias 650a, 652a couple opposite ends of span structure 634a to reference planes 612, 622, respectively. Other vias 650b, 652b couple opposite ends of span structure 634b each to a corresponding one of the reference planes (not shown) that are each stacked with a respective one of reference planes 612, 622. The coplanar arrangement of span structures 632a, 632b, 634a, 634b may enable significant flexibility of section 630 and high-bandwidth communication of signals—e.g., including a differential signal pair—via section 630. To protect signal integrity, a separation between span portions 632a, 632b, a separation between span portions 632a, 634a and/or a separation between span portions 632b, 634b may each be in a range between 60 microns (μm) and 150 μm. However, such dimensions are merely illustrative, and may vary considerable according to implementation-specific details.

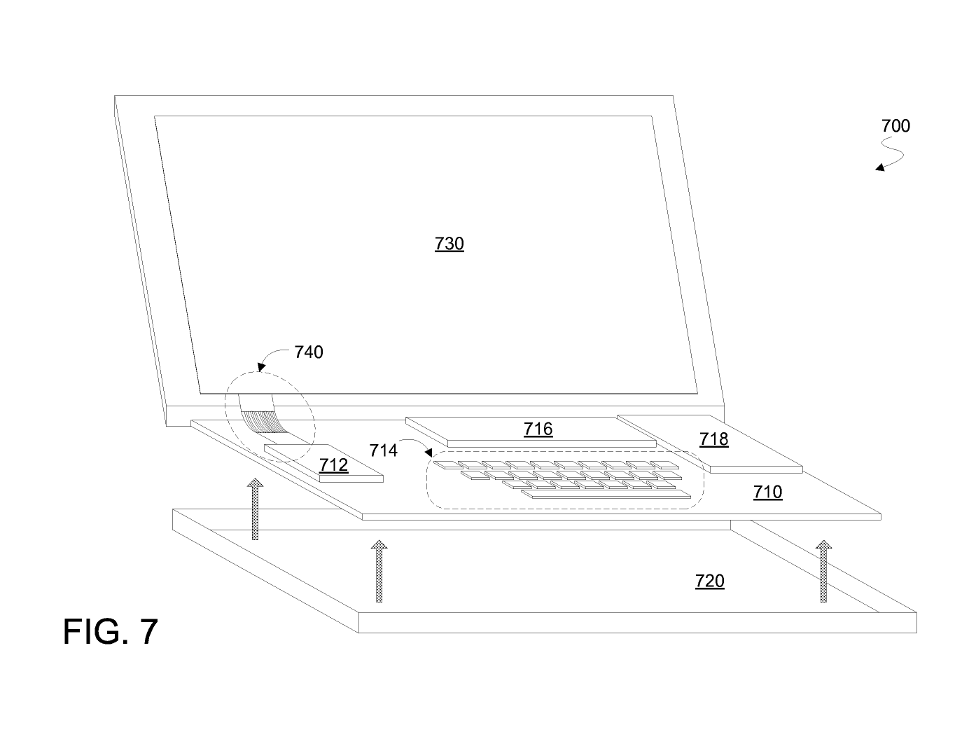

FIG. 7 shows an exploded view of a system 700 including flexible circuit structures to exchange high-bandwidth signaling—e.g., conforming to the Embedded Display Port (eDP) standard, Version 1.0 of the Video Electronics Standards Association (VESA), adopted December 2008—across a hinge according to an embodiment. System 700 may include hardware of any of a variety of computing-capable platforms including, but not limited to, a mobile device (e.g., a smart phone, palmtop, personal digital assistant, etc.), laptop computer, desktop computer, wearable device and/or the like.

System 700 is one example of hardware that includes at least two portions that may be variously articulated relative to one another by a hinge mechanism, where circuitry of the two portions are to exchange high-bandwidth signaling via a flexible circuit that bends with movement of the hinge mechanism. By way of illustration and not limitation, system 700 may include a housing 720 coupled via a hinge mechanism (not shown) to a display 730. Housing 720 may have disposed therein first signaling resources—as represented by the illustrative motherboard 710 and circuit resources 712, 714, 716, 718 coupled thereto. Resources 712, 716 718 represent any of a wide variety of packaged integrated circuit (and/or other) devices, including, for example, random access memory, read-only memory, one or more processors, a memory controller, a wired or wireless network interface and/or the like. Resource 714 represents keyboard circuitry and/or any of a wide variety of other input/output mechanisms such as a mouse, touchpad, touchscreen, speaker, microphone, etc. Circuit resources 712, 714, 716, 718 may be operate for motherboard 710 to exchange signals, via a flexible circuit 740, with another portion of system 700 (such as the illustrative display 730). Display 730 may include circuitry 735 to exchange video, touch, audio and/or other information with motherboard 710 (and/or resources coupled thereto). In an embodiment, structures of flexible circuit 740 (e.g., including span structures, trace portions and reference plane structures) are arranged to allow for high-bandwidth communication via and small radius bending of flexible circuit 740. For example, flexible circuit 740 may include some or all of the features of device 100.

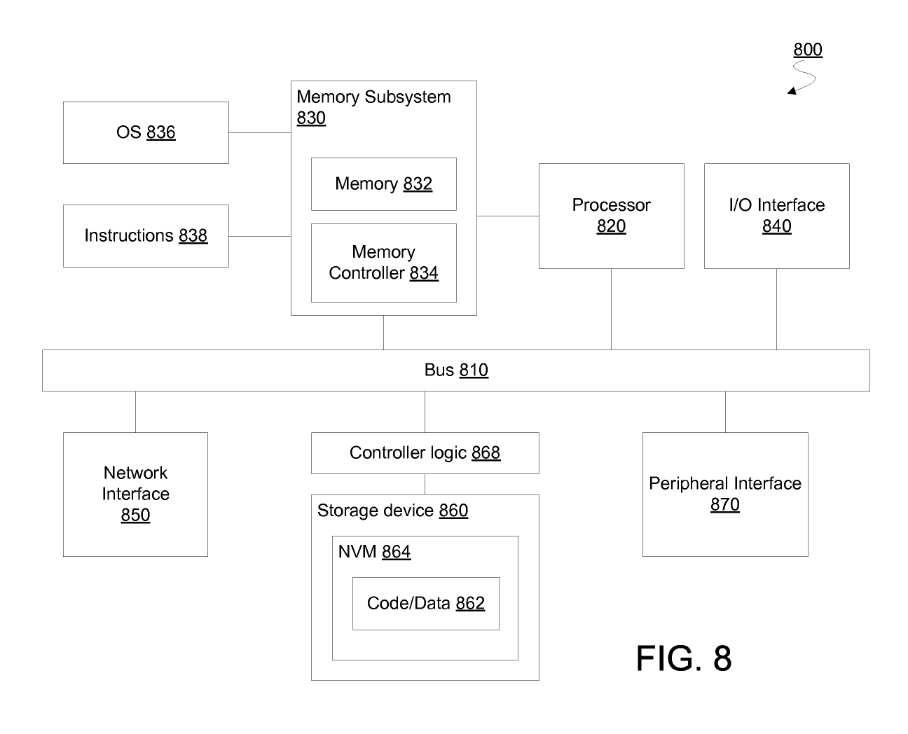

FIG. 8 is a block diagram of an embodiment of a computing system (e.g., including features of system 700) in which a flexible connection may be implemented. System 800 represents a computing device in accordance with any embodiment described herein, and may be a laptop computer, a desktop computer, a server, a gaming or entertainment control system, a scanner, copier, printer, or other electronic device. System 800 may include processor 820, which provides processing, operation management, and execution of instructions for system 800. Processor 820 may include any type of microprocessor, central processing unit (CPU), processing core, or other processing hardware to provide processing for system 800. Processor 820 controls the overall operation of system 800, and may be or include, one or more programmable general-purpose or special-purpose microprocessors, digital signal processors (DSPs), programmable controllers, application specific integrated circuits (ASICs), programmable logic devices (PLDs), or the like, or a combination of such devices.

Memory subsystem 830 represents the main memory of system 800, and provides temporary storage for code to be executed by processor 820, or data values to be used in executing a routine. Memory subsystem 830 may include one or more memory devices such as read-only memory (ROM), flash memory, one or more varieties of random access memory (RAM), or other memory devices, or a combination of such devices. Memory subsystem 830 stores and hosts, among other things, operating system (OS) 836 to provide a software platform for execution of instructions in system 800. Additionally, other instructions 838 are stored and executed from memory subsystem 830 to provide the logic and the processing of system 800. OS 836 and instructions 838 are executed by processor 820.

Storage device 860 may be or include any conventional nonvolatile medium (NVM) 864 for storing large amounts of data in a nonvolatile manner, such as one or more magnetic, solid state, or optical based disks, or a combination. NVM 864 may store code or instructions and data 862 in a persistent state (i.e., the value is retained despite interruption of power to system 800). Access to NVM 864 may be provided with controller logic 868 coupled to (or in some embodiments, included in) storage device 860. For example, controller logic 868 or may be any of the variety of host controller logic to exchange data frames to access NVM 864. Storage device 860 may be generically considered to be a “memory,” although memory 830 is the executing or operating memory to provide instructions to processor 820. Whereas storage 860 is nonvolatile, memory 830 may include volatile memory (i.e., the value or state of the data is indeterminate if power is interrupted to system 800).

Memory subsystem 830 may include memory device 832 where it stores data, instructions, programs, or other items. In one embodiment, memory subsystem 830 includes memory controller 834 to provide access to memory 832—e.g., on behalf of processor 820.

Processor 820 and memory subsystem 830 are coupled to bus/bus system 810. Bus 810 is an abstraction that represents any one or more separate physical buses, communication lines/interfaces, and/or point-to-point connections, connected by appropriate bridges, adapters, and/or controllers. Therefore, bus 810 may include, for example, one or more of a system bus, a Peripheral Component Interconnect (PCI) bus, an Open Core Protocol (OCP) bus, a HyperTransport or industry standard architecture (ISA) bus, a small computer system interface (SCSI) bus, a universal serial bus (USB), or an Institute of Electrical and Electronics Engineers (IEEE) standard 1394 bus (commonly referred to as “Firewire”). The buses of bus 810 may also correspond to interfaces in network interface 850.

System 800 may also include one or more input/output (I/O) interface(s) 840, network interface 850, one or more internal mass storage device(s) 860, and peripheral interface 870 coupled to bus 810. I/O interface 840 may include one or more interface components through which a user interacts with system 800 (e.g., video, audio, and/or alphanumeric interfacing). Network interface 850 provides system 800 the ability to communicate with remote devices (e.g., servers, other computing devices) over one or more networks. Network interface 850 may include an Ethernet adapter, wireless interconnection components, USB (universal serial bus), or other wired or wireless standards-based or proprietary interfaces.

Peripheral interface 870 may include any hardware interface not specifically mentioned above. Peripherals refer generally to devices that connect dependently to system 800. A dependent connection is one where system 800 provides the software and/or hardware platform on which operation executes, and with which a user interacts.

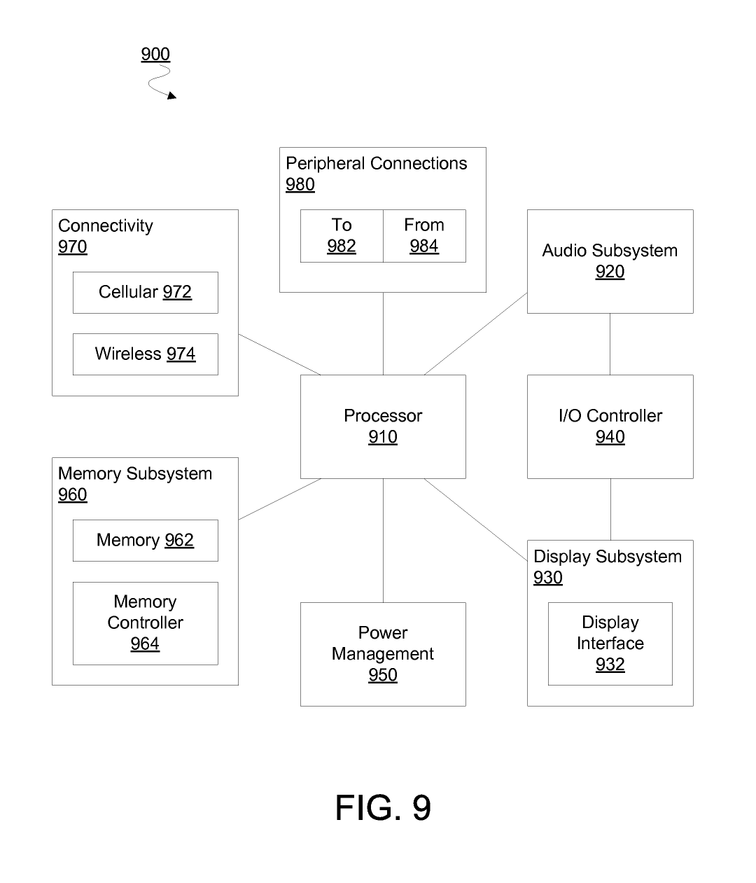

FIG. 9 is a block diagram of an embodiment of a mobile device (e.g., including features of system 700) in which a flexible connection may be implemented. Device 900 represents a mobile computing device, such as a computing tablet, a mobile phone or smartphone, a wireless-enabled e-reader, or other mobile device. It will be understood that certain of the components are shown generally, and not all components of such a device are shown in device 900.

Device 900 may include processor 910, which performs the primary processing operations of device 900. Processor 910 may include one or more physical devices, such as microprocessors, application processors, microcontrollers, programmable logic devices, or other processing means. The processing operations performed by processor 910 include the execution of an operating platform or operating system on which applications and/or device functions are executed. The processing operations include operations related to I/O (input/output) with a human user or with other devices, operations related to power management, and/or operations related to connecting device 900 to another device. The processing operations may also include operations related to audio I/O and/or display I/O.

In one embodiment, device 900 includes audio subsystem 920, which represents hardware (e.g., audio hardware and audio circuits) and software (e.g., drivers, codecs) components associated with providing audio functions to the computing device. Audio functions may include speaker and/or headphone output, as well as microphone input. Devices for such functions may be integrated into device 900, or connected to device 900. In one embodiment, a user interacts with device 900 by providing audio commands that are received and processed by processor 910.

Display subsystem 930 represents hardware (e.g., display devices) and software (e.g., drivers) components that provide a visual and/or tactile display for a user to interact with the computing device. Display subsystem 930 may include display interface 932, which may include the particular screen or hardware device used to provide a display to a user. In one embodiment, display interface 932 includes logic separate from processor 910 to perform at least some processing related to the display. In one embodiment, display subsystem 930 includes a touchscreen device that provides both output and input to a user.

I/O controller 940 represents hardware devices and software components related to interaction with a user. I/O controller 940 may operate to manage hardware that is part of audio subsystem 920 and/or display subsystem 930. Additionally, I/O controller 940 illustrates a connection point for additional devices that connect to device 900 through which a user might interact with the system. For example, devices that may be attached to device 900 might include microphone devices, speaker or stereo systems, video systems or other display device, keyboard or keypad devices, or other I/O devices for use with specific applications such as card readers or other devices.

As mentioned above, I/O controller 940 may interact with audio subsystem 920 and/or display subsystem 930. For example, input through a microphone or other audio device may provide input or commands for one or more applications or functions of device 900. Additionally, audio output may be provided instead of or in addition to display output. In another example, if display subsystem includes a touchscreen, the display device also acts as an input device, which may be at least partially managed by I/O controller 940. There may also be additional buttons or switches on device 900 to provide I/O functions managed by I/O controller 940.

In one embodiment, I/O controller 940 manages devices such as accelerometers, cameras, light sensors or other environmental sensors, gyroscopes, global positioning system (GPS), or other hardware that may be included in device 900. The input may be part of direct user interaction, as well as providing environmental input to the system to influence its operations (such as filtering for noise, adjusting displays for brightness detection, applying a flash for a camera, or other features).

In one embodiment, device 900 includes power management 950 that manages battery power usage, charging of the battery, and features related to power saving operation. Memory subsystem 960 may include memory device(s) 962 for storing information in device 900. Memory subsystem 960 may include nonvolatile (state does not change if power to the memory device is interrupted) and/or volatile (state is indeterminate if power to the memory device is interrupted) memory devices. Memory 960 may store application data, user data, music, photos, documents, or other data, as well as system data (whether long-term or temporary) related to the execution of the applications and functions of system 900.

In one embodiment, memory subsystem 960 includes memory controller 964 (which could also be considered part of the control of system 900, and could potentially be considered part of processor 910). Connectivity 970 may include hardware devices (e.g., wireless and/or wired connectors and communication hardware) and software components (e.g., drivers, protocol stacks) to enable device 900 to communicate with external devices. The device could be separate devices, such as other computing devices, wireless access points or base stations, as well as peripherals such as headsets, printers, or other devices.

Connectivity 970 may include multiple different types of connectivity. To generalize, device 900 is illustrated with cellular connectivity 972 and wireless connectivity 974. Cellular connectivity 972 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 974 refers to wireless connectivity that is not cellular, and may include personal area networks (such as Bluetooth), local area networks (such as WiFi), and/or wide area networks (such as WiMax), or other wireless communication. Wireless communication refers to transfer of data through the use of modulated electromagnetic radiation through a non-solid medium. Wired communication occurs through a solid communication medium.

Peripheral connections 980 include hardware interfaces and connectors, as well as software components (e.g., drivers, protocol stacks) to make peripheral connections. It will be understood that device 900 could both be a peripheral device (“to” 982) to other computing devices, as well as have peripheral devices (“from” 984) connected to it. Device 900 commonly has a “docking” connector to connect to other computing devices for purposes such as managing (e.g., downloading and/or uploading, changing, synchronizing) content on device 900. Additionally, a docking connector may allow device 900 to connect to certain peripherals that allow device 900 to control content output, for example, to audiovisual or other systems.

In addition to a proprietary docking connector or other proprietary connection hardware, device 900 may make peripheral connections 980 via common or standards-based connectors. Common types may include a Universal Serial Bus (USB) connector (which may include any of a number of different hardware interfaces), DisplayPort including MiniDisplayPort (MDP), High Definition Multimedia Interface (HDMI), Firewire, or other type.

In one implementation, a flexible circuit comprises a first section including a first trace portion and a first conductor arranged in a first stacked configuration between sides of the flexible circuit, and a second section including a second trace portion and a second conductor arranged in a second stacked configuration between the sides of the flexible circuit. The flexible circuit further comprises a third section including a first span structure coupled to exchange a first signal, while the first conductor and the second conductor are maintained at a reference potential, between the first trace portion and the second trace portion, wherein the first span structure propagates the first signal along a first plane between the sides of the flexible circuit, and a second span structure coplanar with the first span structure and the first plane, wherein, while the first span structure exchanges the first signal, the second span structure to be maintained at the reference potential, or the second span structure to propagate a second signal, complementary to the first signal, along a line of direction in parallel with the sides of the flexible circuit and in parallel with the first plane.

In an embodiment, the third section further comprises a third span structure coplanar with the first span structure, wherein the first span structure is between the second span structure and the third span structure, wherein, while the first span structure exchanges the first signal, the second span structure and the third span structure are to be maintained at the reference potential. In another embodiment, the first stacked configuration further comprises a third conductor, and the second stacked configuration further comprises a fourth conductor, wherein the second span structure is coupled to the first conductor and the second conductor, and wherein the third span structure is coupled to the third conductor and the fourth conductor. In another embodiment, the first plane is a midline plane between the sides of the flexible circuit. In another embodiment, the first plane extends through the first trace portion and the second trace portion.

In another embodiment, while the first span structure exchanges the first signal, the second span structure is to propagate the second signal, and wherein the third section further comprises a third span structure and a fourth span structure each coplanar with the first span structure, the third span structure and the fourth span structure coupled to be maintained at the reference potential while the first span structure exchanges the first signal, wherein the first span structure and the second span structure are each between the third span structure and the fourth span structure. In another embodiment, the flexible circuit further comprises a tapered portion coupled between the first trace portion and the first span structure.

In another implementation, method by a flexible circuit comprises exchanging a first signal between a first trace portion and a second trace portion, wherein a first section of the flexible circuit include the first trace portion and a first conductor arranged in a first stacked configuration between sides of the flexible circuit, wherein a second section of the flexible circuit include the second trace portion and a second conductor arranged in a second stacked configuration between the sides of the flexible circuit, the exchanging including a first span structure propagating the first signal along a first plane between the sides of the flexible circuit, wherein a third section of the flexible circuit, between the first section and the second section, includes the first span structure and a second span structure coplanar with the first plane and the first span structure. The method further comprise, during the exchanging, maintaining the first conductor and the second conductor at a reference potential, and maintaining the second span structure at the reference potential, or exchanging via the second span structure a second signal, complementary to the first signal, along the first plane.

In an embodiment, the method further comprises, while the first span structure exchanges the first signal, maintaining the second span structure and a third span structure of the third section at the reference potential, wherein the third span structure is coplanar with the first span structure, and wherein the first span structure is between the second span structure and the third span structure. In another embodiment, the first stacked configuration further comprises a third conductor, wherein the second stacked configuration further comprises a fourth conductor, wherein the second span structure is coupled to the first conductor and the second conductor, and wherein the third span structure is coupled to the third conductor and the fourth conductor.

In another embodiment, the first plane is a midline plane between the sides of the flexible circuit. In another embodiment, the first plane extends through the first trace portion and the second trace portion. In another embodiment, during the exchanging, the second span structure propagates the second signal, wherein the method further comprises, during the exchanging, maintaining a third span structure of the third section and a fourth span structure of the third section each at the reference potential, the third span structure and the fourth span structure each coplanar with the first span structure, wherein the first span structure and the second span structure are each between the third span structure and the fourth span structure. In another embodiment, the flexible circuit includes a tapered portion coupled between the first trace portion and the first span structure.

In another implementation, a system comprises a flexible circuit including a first section comprising a first trace portion and a first conductor arranged in a first stacked configuration between sides of the flexible circuit, and a second section comprising a second trace portion and a second conductor arranged in a second stacked configuration between the sides of the flexible circuit. The flexible circuit further includes a third section comprising a first span structure coupled to exchange a first signal, while the first conductor and the second conductor are maintained at a reference potential, between the first trace portion and the second trace portion, wherein the first span structure propagates the first signal along a first plane between the sides of the flexible circuit, and a second span structure coplanar with the first span structure and the first plane, wherein, while the first span structure exchanges the first signal, the second span structure to be maintained at the reference potential, or the second span structure to propagate a second signal, complementary to the first signal, along a line of direction in parallel with the sides of the flexible circuit and in parallel with the first plane. The system further comprises a display device coupled to the flexible circuit, the display device to display an image based on the first signal.

In another embodiment, the third section further comprises a third span structure coplanar with the first span structure, wherein the first span structure is between the second span structure and the third span structure, wherein, while the first span structure exchanges the first signal, the second span structure and the third span structure are to be maintained at the reference potential. In another embodiment, the first stacked configuration further comprises a third conductor, the second stacked configuration further comprises a fourth conductor, wherein the second span structure is coupled to the first conductor and the second conductor, and wherein the third span structure is coupled to the third conductor and the fourth conductor.

In another embodiment, the first plane is a midline plane between the sides of the flexible circuit. In another embodiment, the first plane extends through the first trace portion and the second trace portion. In another embodiment, while the first span structure exchanges the first signal, the second span structure is to propagate the second signal, wherein the third section further comprises a third span structure and a fourth span structure each coplanar with the first span structure, the third span structure and the fourth span structure coupled to be maintained at the reference potential while the first span structure exchanges the first signal, wherein the first span structure and the second span structure are each between the third span structure and the fourth span structure.

Techniques and architectures for providing signaling across a flexible connection are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A flexible circuit comprising:
a first section including a first trace portion and a first conductor arranged in a first stacked configuration between sides of the flexible circuit;
a second section including a second trace portion and a second conductor arranged in a second stacked configuration between the sides of the flexible circuit; and
a third section including:
a first span structure coupled to exchange a first signal, while the first conductor and the second conductor are maintained at a reference potential, between the first trace portion and the second trace portion, wherein the first span structure is to propagate the first signal along a first plane between the sides of the flexible circuit; and
a second span structure coplanar with the first span structure and the first plane, wherein, while the first span structure exchanges the first signal:
the second span structure to be maintained at the reference potential; or
the second span structure to propagate a second signal, complementary to the first signal, along a line of direction in parallel with the sides of the flexible circuit and in parallel with the first plane.

2. The flexible circuit of claim 1, the third section further comprising a third span structure coplanar with the first span structure, wherein the first span structure is between the second span structure and the third span structure, wherein, while the first span structure exchanges the first signal, the second span structure and the third span structure are to be maintained at the reference potential.

3. The flexible circuit of claim 2, the first stacked configuration further comprising a third conductor, the second stacked configuration further comprising a fourth conductor, wherein the second span structure is coupled to the first conductor and the second conductor, and wherein the third span structure is coupled to the third conductor and the fourth conductor.

4. The flexible circuit of claim 1, wherein the first plane is a midline plane between the sides of the flexible circuit.

5. The flexible circuit of claim 1, wherein the first plane extends through the first trace portion and the second trace portion.

6. The flexible circuit of claim 1, wherein, while the first span structure exchanges the first signal, the second span structure is to propagate the second signal; and
wherein the third section further comprises a third span structure and a fourth span structure each coplanar with the first span structure, the third span structure and the fourth span structure coupled to be maintained at the reference potential while the first span structure exchanges the first signal, wherein the first span structure and the second span structure are each between the third span structure and the fourth span structure.

7. The flexible circuit of claim 1, further comprising a tapered portion coupled between the first trace portion and the first span structure.

8. A method by a flexible circuit, the method comprising:
exchanging a first signal between a first trace portion and a second trace portion, wherein a first section of the flexible circuit include the first trace portion and a first conductor arranged in a first stacked configuration between sides of the flexible circuit, wherein a second section of the flexible circuit include the second trace portion and a second conductor arranged in a second stacked configuration between the sides of the flexible circuit, the exchanging including a first span structure propagating the first signal along a first plane between the sides of the flexible circuit, wherein a third section of the flexible circuit, between the first section and the second section, includes the first span structure and a second span structure coplanar with the first plane and the first span structure;
during the exchanging:
maintaining the first conductor and the second conductor at a reference potential; and
maintaining the second span structure at the reference potential or exchanging via the second span structure a second signal, complementary to the first signal, along the first plane.

9. The method of claim 8, further comprising:
while the first span structure exchanges the first signal, maintaining the second span structure and a third span structure of the third section at the reference potential, wherein the third span structure is coplanar with the first span structure, and wherein the first span structure is between the second span structure and the third span structure.

10. The method of claim 9, wherein the first stacked configuration further comprises a third conductor, wherein the second stacked configuration further comprises a fourth conductor, wherein the second span structure is coupled to the first conductor and the second conductor, and wherein the third span structure is coupled to the third conductor and the fourth conductor.

11. The method of claim 8, wherein the first plane is a midline plane between the sides of the flexible circuit.

12. The method of claim 8, wherein the first plane extends through the first trace portion and the second trace portion.

13. The method of claim 8, wherein, during the exchanging, the second span structure is to propagate the second signal, the method further comprising:
during the exchanging, maintaining a third span structure of the third section and a fourth span structure of the third section each at the reference potential, the third span structure and the fourth span structure each coplanar with the first span structure, wherein the first span structure and the second span structure are each between the third span structure and the fourth span structure.

14. The method of claim 8, wherein the flexible circuit includes a tapered portion coupled between the first trace portion and the first span structure.

15. A system comprising:
a flexible circuit including:
a first section comprising a first trace portion and a first conductor arranged in a first stacked configuration between sides of the flexible circuit;
a second section comprising a second trace portion and a second conductor arranged in a second stacked configuration between the sides of the flexible circuit; and
a third section comprising:
a first span structure coupled to exchange a first signal, while the first conductor and the second conductor are maintained at a reference potential, between the first trace portion and the second trace portion, wherein the first span structure is to propagate the first signal along a first plane between the sides of the flexible circuit; and
a second span structure coplanar with the first span structure and the first plane, wherein, while the first span structure exchanges the first signal:
the second span structure to be maintained at the reference potential; or
the second span structure to propagate a second signal, complementary to the first signal, along a line of direction in parallel with the sides of the flexible circuit and in parallel with the first plane; and
a display device coupled to the flexible circuit, the display device to display an image based on the first signal.

16. The system of claim 15, the third section further comprising a third span structure coplanar with the first span structure, wherein the first span structure is between the second span structure and the third span structure, wherein, while the first span structure exchanges the first signal, the second span structure and the third span structure are to be maintained at the reference potential.

17. The system of claim 16, the first stacked configuration further comprising a third conductor, the second stacked configuration further comprising a fourth conductor, wherein the second span structure is coupled to the first conductor and the second conductor, and wherein the third span structure is coupled to the third conductor and the fourth conductor.

18. The system of claim 15, wherein the first plane is a midline plane between the sides of the flexible circuit.

19. The system of claim 15, wherein the first plane extends through the first trace portion and the second trace portion.

20. The system of claim 15, wherein, while the first span structure exchanges the first signal, the second span structure is to propagate the second signal; and
wherein the third section further comprises a third span structure and a fourth span structure each coplanar with the first span structure, the third span structure and the fourth span structure coupled to be maintained at the reference potential while the first span structure exchanges the first signal, wherein the first span structure and the second span structure are each between the third span structure and the fourth span structure.
